(19) United States
(12) Patent Application Publication
(10) Pub. No.: US 2019/0312164 A1
(43) Pub. Date: Oct. 10, 2019

(54) SOLAR CELL MODULE

(71) Applicant: PANASONIC INTELLECTUAL PROPERTY MANAGEMENT CO., LTD., Osaka (JP)

(72) Inventors: Motohiko SUGIYAMA, Osaka (JP); Naoki KURIZOE, Osaka (JP); Takeshi UEDA, Hyogo (JP); Yoshimitsu IKOMA, Nara (JP)

(21) Appl. No.: 16/348,621

(22) PCT Filed: Dec. 13, 2017
(86) PCT No.: PCT/JP2017/044658

§ 371 Date: May 9, 2019

(30) Foreign Application Priority Data
Dec. 15, 2016 (JP) 2016-243171
Aug. 22, 2017 (JP) 2017-159400

(51) Int. Cl. H01L 31/048

(52) U.S. Cl. CPC H01L 31/0481

(57) ABSTRACT

A solar cell module includes a front surface substrate, a seal layer arranged under the front surface substrate to seal a photoelectric converter, a low thermal expansion-contraction layer arranged under the seal layer, and a rear surface substrate arranged under the low thermal expansion-contraction layer. The solar cell module further includes a stress-reducing resin layer arranged between the low thermal expansion-contraction layer and the rear surface substrate. The low thermal expansion-contraction layer has a smaller coefficient of linear expansion than the rear surface substrate, and the stress-reducing resin layer has a smaller tensile modulus of elasticity than the low thermal expansion-contraction layer and the rear surface substrate.

### TECHNICAL FIELD

The present invention relates to solar cell modules, and more particularly, to a solar cell module resistant to damage to a photoelectric converter caused by thermal expansion or contraction.

### BACKGROUND ART

Various solar cell modules have been developed in response to increasing demand for photovoltaic power generation, which is the conversion of light energy into electrical energy, in view of environmental protection.

For example, Patent Document 1 discloses a solar cell module including a front sheet, a front-side filler layer, solar cell elements as photovoltaic cells, a back-side filler layer, and a back sheet, which are sequentially stacked.

### CITATION LIST

### Patent Literature

Patent Document 1: Japanese Patent Application Publication No. 2013-145807

### SUMMARY OF INVENTION

The front sheet, the front-side filler layer, the back-side filler layer, and the back sheet disclosed in Patent Document 1 are mainly made of resin material. If the resin material included in these elements thermally expands or contracts due to irradiated heat of sunlight, thermal stress may be applied to the solar cell elements or connecting members connecting the solar cell elements, thus causing damage to the solar cell elements or cutoff of the connecting tabs.

In view of the foregoing conventional problems, the present invention provides a solar cell module resistant to damage to a photoelectric converter caused by thermal expansion or contraction.

In order to solve the problems described above, a solar cell module according to an aspect of the present invention includes a front surface substrate, a seal layer arranged under the front surface substrate to seal a photoelectric converter, a low thermal expansion-contraction layer arranged under the seal layer, and a rear surface substrate arranged under the low thermal expansion-contraction layer. The solar cell module further includes a stress-reducing resin layer arranged between the low thermal expansion-contraction layer and the rear surface substrate. The low thermal expansion-contraction layer has a smaller coefficient of linear expansion than the rear surface substrate. The stress-reducing resin layer has a smaller tensile modulus of elasticity than the low thermal expansion-contraction layer and the rear surface substrate.

### BRIEF DESCRIPTION OF DRAWINGS

FIG. 1 is a cross-sectional view illustrating a solar cell module according to the present embodiment.

FIG. 2 is a top view illustrating the solar cell module according to the present embodiment.

FIG. 3 is a schematic top view illustrating a low thermal expansion-contraction layer provided with slits.

FIG. 4 is a cross-sectional view of the solar cell module taken along line A-A in FIG. 3.

FIG. 5 is a schematic top view illustrating a seal layer partly bonded to a stress-reducing resin layer.

FIG. 6 is a cross-sectional view of the solar cell module taken along line B-B in FIG. 5.

FIG. 7 is a cross-sectional view illustrating the solar cell module according to the present embodiment.

FIG. 8 is a cross-sectional view illustrating the solar cell module according to the present embodiment.

FIG. 9 is a cross-sectional view illustrating the solar cell module according to the present embodiment.

FIG. 10 is a cross-sectional view illustrating the solar cell module according to the present embodiment.

FIG. 11 is a cross-sectional view illustrating the solar cell module according to the present embodiment.

FIG. 12 is a cross-sectional view illustrating the solar cell module according to the present embodiment.

FIG. 13 is a schematic top view illustrating a solar cell module used for Example 7 to Example 10.

FIG. 14 is a schematic top view illustrating a solar cell module used for Example 11 to Example 15.

FIG. 15 is a graph showing a relationship between an area proportion of the low thermal expansion-contraction layer and a variation in distance between solar cells when a thermal load is changed from 120° C. to 30° C.

### DESCRIPTION OF EMBODIMENTS

A solar cell module according to the present embodiment will be described in detail below with reference to the drawings. The dimensions of elements in the drawings may be exaggerated for illustration purposes, and are not necessarily drawn to scale. The respective drawings are described with a three-dimensional coordinate system defined by x, y, and z axes, and the positive direction of the respective axes conforms to a direction indicated by the corresponding arrow.

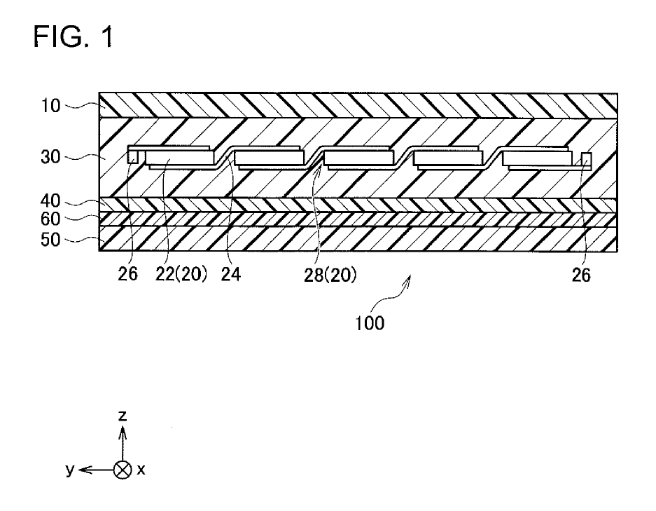

FIG. 1 is a cross-sectional view illustrating the solar cell module 100 according to the present embodiment. The solar cell module 100 according to the present embodiment includes a front surface substrate 10, a seal layer 30 arranged under the front surface substrate 10 to seal a photoelectric converter 20, a low thermal expansion-contraction layer 40 arranged under the seal layer 30, and a rear surface substrate 50 arranged under the low thermal expansion-contraction layer 40.

The low thermal expansion-contraction layer 40 according to the present embodiment has a smaller coefficient of linear expansion than the rear surface substrate 50. Thermal stress increases in proportion to the coefficient of linear expansion, as shown in the following formula (1):

[Math. 1]

σ=EαΔT (1)

where σ is the thermal stress (Pa), E is a tensile modulus of elasticity which is a Young's modulus (Pa), a is the coefficient of linear expansion (K⁻¹), and ΔT is a variation in temperature (K).

Since the thermal expansion or contraction of the low thermal expansion-contraction layer 40 is small, the thermal expansion or contraction of the rear surface substrate 50 remains small if a temperature variation is caused in the rear surface substrate 50, so as to reduce the thermal stress of the rear surface substrate 50 transmitted through the seal layer 30.

The tensile modulus of elasticity of the rear surface substrate 50 tends to be high in the solar cell module 100 which needs to have high rigidity, leading to an increase in the thermal stress of the rear surface substrate 50. The thermal expansion or contraction of the rear surface substrate 50 causes the thermal expansion or contraction of the low thermal expansion-contraction layer 40, which would fail to sufficiently reduce the thermal stress of the rear surface substrate 50.

The solar cell module 100 according to the present embodiment thus further includes a stress-reducing resin layer 60 arranged between the low thermal expansion-contraction layer 40 and the rear surface substrate 50. The stress-reducing resin layer 60 has a smaller tensile modulus of elasticity than the low thermal expansion-contraction layer 40 and the rear surface substrate 50. The stress-reducing resin layer 60 having a smaller tensile modulus of elasticity serves as a cushion to reduce the thermal stress of the rear surface substrate 50, so as to prevent the thermal expansion or contraction of the rear surface substrate 50 from being transferred to the low thermal expansion-contraction layer 40, thus preventing damage to the photoelectric converter 20. The respective constituent elements are described in detail below.

<Front Surface Substrate 10>

The front surface substrate 10 is arranged on the light-receiving surface side of the solar cell module 100 to protect the surface of the solar cell module 100. As used in the present embodiment, the front surface substrate 10 side also refers to the light-receiving surface side, and the rear surface substrate 50 side also refers to the side opposite to the light-receiving surface side for illustration purposes. Another layer may be provided on the outer side of each of the front surface substrate 10 and the rear surface substrate 50 as necessary. The front surface substrate 10 may have any shape that can protect the surface of the solar cell module 100, and may have a circular shape, an elliptic shape, or a polygonal shape such as a rectangular shape, which is determined depending on the purpose. Although FIG. 1 illustrates the front surface substrate 10 having a rectangular shape in cross section according to the present embodiment, the front surface substrate 10 may be concave in the stacked direction of the respective layers of the solar cell module 100.

A material included in the front surface substrate 10 is determined as appropriate, and may be at least one material selected from the group consisting of glass, polyethylene (PE), polypropylene (PP), cyclic polyolefin, polycarbonate (PC), polymethyl methacrylate (PMMA), polytetrafluoroethylene (PTFE), polystyrene (PS), polyethylene terephthalate (PET), and polyethylene naphthalate (PEN). The front surface substrate 10 preferably includes glass or PC having higher resistance to shock and higher transmittance so as to protect the surface of the solar cell module 100. The front surface substrate 10 more preferably includes PC in view of a reduction in weight.

The front surface substrate 10 may have any thickness that can protect the surface of the solar cell module 100, and preferably has a thickness in a range of 0.1 mm to 15 mm, and more preferably in a range of 0.5 mm to 10 mm. The front surface substrate 10 with the thickness in the above range can protect the solar cell module 100 sufficiently and allow light to be transmitted to the photoelectric converter 20 efficiently.

The tensile modulus of elasticity of the front surface substrate 10 is preferably, but not necessarily, set in a range of 1.0 GPa or greater to 10.0 GPa or smaller, and more preferably in a range of 2.3 GPa or greater to 2.5 GPa or smaller. The front surface substrate 10 with the tensile modulus of elasticity set in the above range can sufficiently protect the surface of the solar cell module 100 from external shock. The tensile modulus of elasticity can be measured in accordance with Japanese Industrial Standards JIS K7161-1 (Plastics—Determination of tensile properties—Part 1: General principles) under the conditions of a test temperature of 25° C. and a test velocity of 100 mm per minute according to the following formula (2):

Eₜ=(σ₂−σ₁)/(ε₂−ε₁) (2)

where Eₜ is the tensile modulus of elasticity (Pa), σ₁ is a stress (Pa) measured at a distortion of ε₁=0.0005, and σ₂ is a stress (Pa) measured at a distortion of ε₂=0.0025.

A total luminous transmittance of the front surface substrate 10 is preferably, but not necessarily, set in a range of 80% to 100%, and more preferably in a range of 85% to 95%. The front surface substrate 10 with the total luminous transmittance set in the above range can allow light to be transmitted to the photoelectric converter 20 efficiently. The total luminous transmittance can be measured in accordance with JIS K7361-1 (Plastics—Determination of the total luminous transmittance of transparent materials—Part 1: Single beam instrument).

<Photoelectric Converter 20>

The photoelectric converter 20 may have any configuration that converts light energy into electrical energy. The photoelectric converter 20 according to the present embodiment may be either a single solar cell 22 or a solar cell string 28. Alternatively, a combination of the solar cell string 28 and connecting leads 26 may serve as the photoelectric converter 20.

The solar cell 22 may be a silicon solar cell, a compound-based solar cell, and an organic solar cell, for example. Examples of silicon solar cells include a monocrystalline silicon solar cell, a polycrystalline silicon solar cell, a microcrystalline silicon solar cell, and an amorphous silicon solar cell. Examples of compound-based solar cells include a GaAs solar cell, a CIS solar cell, SIGS solar cell, and a CdTe solar cell. Examples of organic solar cells include a dye-sensitized solar cell and an organic thin-film solar cell. Alternatively, a heterojunction solar cell or a multi-junction solar cell may be used as the solar cell 22.

The shape of the solar cell 22 is determined as appropriate, and may be a plate-like state having a front surface, a rear surface, and side surfaces. The front surface may face the front surface substrate 10 on the light-receiving surface side. The rear surface may face the rear surface substrate 50 on the side opposite to the light-receiving surface side. The side surfaces may be interposed between the front surface and the rear surface to define the respective sides of the plate-like shape. The specific shape of the solar cell 22 is determined as appropriate, and may be a rectangular plate-like shape.

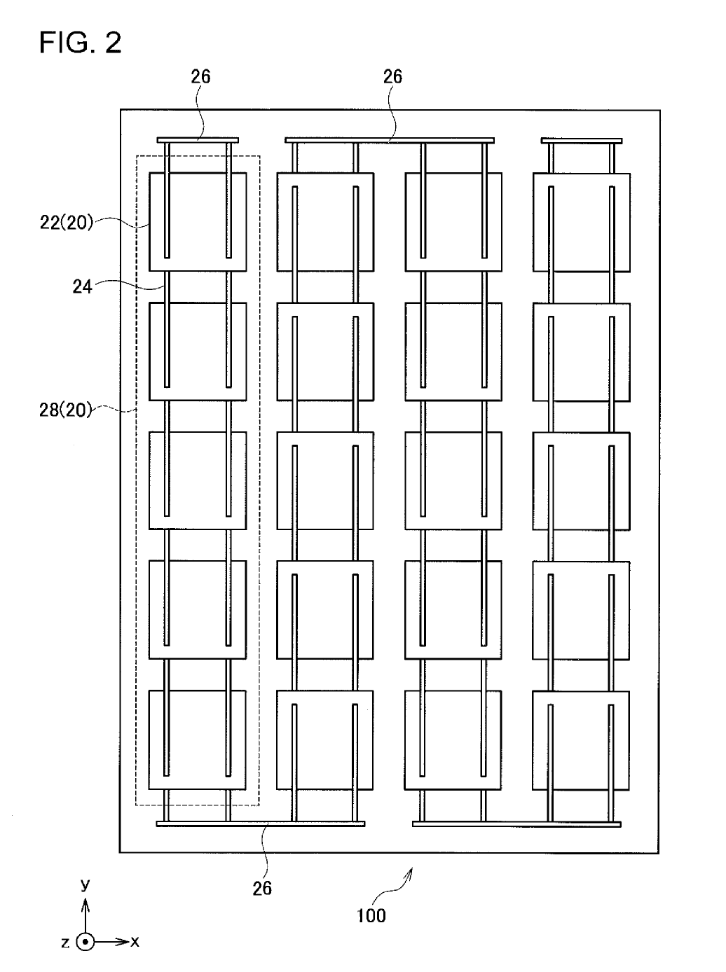

The adjacent solar cells 22 can be electrically connected to each other via connecting members 24 to compose the solar cell string 28. The solar cell string 28 is obtained such that a busbar electrode of each of the aligned solar cells 22 on the light-receiving surface side is electrically connected to a busbar electrode of its adjacent solar cell 22 on the side opposite to the light-receiving surface side via the connecting members 24, as shown in FIG. 1 and FIG. 2. The connecting leads 26 can electrically connect the adjacent two solar cell strings 28 together.

FIG. 2 illustrates the configuration according to the present embodiment in which the five solar cells 22 are aligned in the y-axis direction and connected in series via the connecting members 24 so as to compose the single solar cell string 28. FIG. 2 also illustrates the configuration according to the present embodiment in which the four solar cell strings 28 are arranged in parallel in the x-axis direction and are electrically connected to each other via the connecting leads 26. The embodiment illustrated in FIG. 2 is an example and is not limited to the number and the arrangement of the solar cells 22 described above.

The respective connecting members 24 may have any shape and may include any material that can electrically connect the respective solar cells 22 together, and may be tab leads each made of a long narrow metal foil. The material included in the connecting members 24 may be copper, for example. The connecting members 24 may be soldered or coated with silver.

The connecting members 24 and the busbar electrodes may be connected together with resin. The resin may be either conductive or nonconductive. For nonconductive resin, the tab leads and the busbar electrodes are directly connected to each other to achieve electrical connection. Alternatively, the tab leads and the busbar electrodes may be connected by soldering, instead of resin.

Although not shown, the solar cells 22 on the light receiving surface and the opposite side of the light-receiving surface may be provided with a plurality of finger electrodes extending parallel to each other in the x-axis direction. The busbar electrodes extending in the y-axis direction may be orthogonally connected to the finger electrodes.

<Seal Layer 30>

The seal layer 30 is arranged under the front surface substrate 10 to seal the photoelectric converter 20. The seal layer 30 thus can protect the photoelectric converter 20 from external shock. The seal layer 30 may be in direct contact with the front surface substrate 10 with no members interposed therebetween, or another layer such as a bonding layer or a functional layer may be provided between the seal layer 30 and the front surface substrate 10. The seal layer 30 may have any shape which is determined as appropriate depending on the purpose, including a circular shape, an elliptic shape, or a polygonal shape such as a rectangular shape, as in the case of the front surface substrate 10. The seal layer 30 may have a rectangular shape in cross section, or may be concave in the stacked direction of the respective layers (in the z-axis direction) of the solar cell module 100, as in the case of the front surface substrate 10.

A material included in the seal layer 30 is determined as appropriate, and may be at least one material selected from the group consisting of thermoplastic resin such as an ethylene-vinyl acetate copolymer (EVA), polyvinyl butyral (PVB), polyethylene terephthalate (PET), polyolefin (PO), and polyimide (PI), thermosetting resin such as epoxy, urethane, and polyimide, and gel such as silicone gel, acrylic gel, and urethane gel. These resins may be used as modified resin, or may be combined together. The seal layer 30 preferably includes an ethylene-vinyl acetate copolymer (EVA) or polyolefin (PO) in view of the protecting properties of the photoelectric converter 20.

The tensile modulus of elasticity of the seal layer 30 is preferably, but not necessarily, set in a range smaller than that of the front surface substrate 10. In particular, the tensile modulus of elasticity of the seal layer 30 is preferably set in a range of 0.005 GPa or greater to smaller than 1.0 GPa, and more preferably in a range of 0.01 GPa or greater to smaller than 0.5 GPa. The seal layer 30 with the tensile modulus of elasticity set to the above lower limit can prevent displacement of the photoelectric converter 20. The seal layer 30 with the tensile modulus of elasticity set to the above upper limit can prevent damage to the photoelectric converter 20 and the connecting members 24 caused by thermal expansion or contraction of the seal layer 30. The tensile modulus of elasticity of the sealing member 30 can be measured in accordance with JIS K7161-1, for example, as in the case of the front surface substrate 10.

The seal layer 30 preferably, but not necessarily, has a thickness set in a range of 0.1 mm or greater to 10 mm or less, and more preferably in a range of 0.2 mm or greater to 1.0 mm or less. The seal layer 30 with the thickness set in the above range can protect the photoelectric converter 20 sufficiently and allow light to be transmitted to the photoelectric converter 20 efficiently.

The seal layer 30 preferably, but not necessarily, has a total luminous transmittance set in a range of 60% to 100%, and more preferably in a range of 70% to 95%. The total luminous transmittance of the seal layer 30 is still more preferably set in a range of 80% to 95%. The seal layer 30 with the total luminous transmittance set in the above range can allow light to be transmitted to the photoelectric converter 20 efficiently. The total luminous transmittance can be measured in accordance with the prescription described in JIS K7361-1, for example.

The seal layer 30 may include two or more kinds of different materials to form, for example, two different layers of a seal layer on the light-receiving surface side, and a seal layer on the side opposite to the light-receiving surface side defined about the photoelectric converter 20 in the seal layer 30. The seal layer on the light-receiving surface side preferably has a smaller tensile modulus of elasticity than the seal layer on the side opposite to the light-receiving surface side. The seal layer 30 with this structure can absorb external shock such as hail by the seal layer on the light-receiving surface side, and can rigidly hold the photoelectric converter 20 by the seal layer on the side opposite to the light-receiving surface side.

<Low Thermal Expansion-Contraction Layer 40>

The low thermal expansion-contraction layer 40 is arranged under the seal layer 30. The low thermal expansion-contraction layer 40 has a smaller coefficient of linear expansion than the rear surface substrate 50. The inclusion of the low thermal expansion-contraction layer 40 in the solar cell module 100 according to the present embodiment can prevent thermal expansion or contraction of the solar cell module 100 including the seal layer 30, and thus can prevent damage to the photoelectric converter 20 caused by thermal stress. The coefficient of linear expansion can be measured in accordance with JIS K7197:2012 (Testing method for linear thermal expansion coefficient of plastics by thermomechanical analysis). The low thermal expansion-contraction layer 40 preferably has a smaller coefficient of linear expansion than both the seal layer 30 and the rear surface substrate 50.

The coefficient of linear expansion of the low thermal expansion-contraction layer 40 is preferably set to 20×10⁻⁶ K⁻¹ or smaller. The low thermal expansion-contraction layer 40 with the coefficient of linear expansion set in this range can effectively prevent damage to the photoelectric converter 20 caused by thermal stress. The coefficient of linear expansion of the low thermal expansion-contraction layer 40 is more preferably set in a range of greater than 0 K⁻¹ to 10×10⁻⁶ K⁻¹ or smaller, and still more preferably in a range of greater than 0 K⁻¹ to 7×10⁻⁶ K⁻¹ or smaller.

The photoelectric converter 20 is preferably the solar cell string 28 in which adjacent solar cells 22 are electrically connected to each other via the connecting members 24. The coefficient of linear expansion of the low thermal expansion-contraction layer 40 is preferably set to 20×10⁻⁶ K⁻¹ or smaller in the connected direction of the adjacent solar cells 22, as viewed in the stacked direction of the low thermal expansion-contraction layer 40 and the rear surface substrate 50. Setting the coefficient of linear expansion in this range can prevent damage to the photoelectric converter 20 caused by thermal stress if the low thermal expansion-contraction layer 40 is anisotropic and if the connected direction of the solar cells 22 is different from the thermally expanding-contracting direction of the low thermal expansion-contraction layer 40 as viewed in the stacked direction of the low thermal expansion-contraction layer 40 and the rear surface substrate 50. As used herein, the expression “the low thermal expansion-contraction layer 40 is anisotropic” encompasses a case in which the low thermal expansion-contraction layer 40 is fiber-reinforced plastics in which fibers oriented in one direction are impregnated with resin, for example.

The low thermal expansion-contraction layer 40 may be in direct contact with the seal layer 30 with no members interposed therebetween, or another layer such as a bonding layer or a functional layer may be provided between the low thermal expansion-contraction layer 40 and the seal layer 30. The low thermal expansion-contraction layer 40 may have any shape which is determined as appropriate depending on the purpose, including a circular shape, an elliptic shape, or a polygonal shape such as a rectangular shape, as in the case of the front surface substrate 10. The low thermal expansion-contraction layer 40 may have a rectangular shape in cross section, or may be concave in the stacked direction of the respective layers (in the z-axis direction) of the solar cell module 100, as in the case of the low thermal expansion-contraction layer 40.

The low thermal expansion-contraction layer 40 preferably, but not necessarily, includes a material containing carbon material, cellulose, glass, or ceramic having a relatively small coefficient of linear expansion. Examples of materials containing carbon material include carbon fiber-reinforced plastic (CFRP) and carbon filler-containing resin. Examples of materials containing cellulose include paper and cellulose nanofiber-containing resin (CNF-containing resin). Examples of materials containing glass include a glass plate and glass fiber-containing resin. The material containing ceramic may be a ceramic sheet, for example. The low thermal expansion-contraction layer 40 more preferably includes at least one material selected from the group consisting of carbon fiber-reinforced plastic, glass, and cellulose nanofiber in view of the properties of the coefficient of linear expansion and rigidity. The low thermal expansion-contraction layer 40 particularly preferably includes at least one material selected from the group consisting of carbon fiber-reinforced plastic, glass fiber-containing resin, and cellulose nanofiber in view of the properties of the coefficient of linear expansion and rigidity.

The low thermal expansion-contraction layer 40 preferably, but not necessarily, has a tensile modulus of elasticity set in a range greater than that of the front surface substrate 10. In particular, the tensile modulus of elasticity of the low thermal expansion-contraction layer 40 is preferably set in a range of 20 GPa to 250 GPa, and more preferably in a range of 40 GPa to 140 GPa. Setting the tensile modulus of elasticity in the above range can prevent a separation of the low thermal expansion-contraction layer 40 from the seal layer 30, and can further decrease the thermal stress of the rear surface substrate 50 transmitted to the seal layer 30. The tensile modulus of elasticity can be measured in accordance with the prescription described in JIS K7161-1, for example, as in the case of the front surface substrate 10.

The low thermal expansion-contraction layer 40 preferably, but not necessarily, has a thickness set in a range of 0.05 mm or greater to 0.5 mm or less, and more preferably in a range of 0.1 mm or greater to 0.2 mm or less. The low thermal expansion-contraction layer 40 with the thickness set in the above range can decrease the thermal stress of the rear surface substrate 50 transmitted to the seal layer 30 while an increase in cost is avoided.

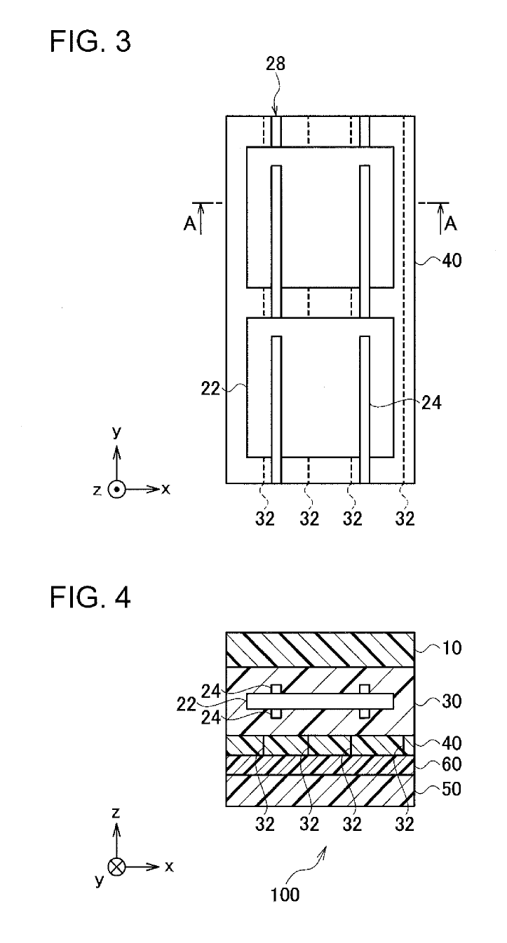

As shown in FIG. 3 and FIG. 4, the low thermal expansion-contraction layer 40 may have a plurality of slits 32 penetrating from the seal layer 30 to the stress-reducing resin layer 60. FIG. 3 and FIG. 4 illustrate the embodiment including the slits 32 which extend in the connected direction of the adjacent solar cells 22 (in the y-axis direction) and are arranged substantially parallel to each other. The slits 32 enable the rear surface substrate 50 to be bent easily on the x-y axis plane, not just in a single-axis direction of the x-axis direction or the y-axis direction, for example, if the low thermal expansion-contraction layer 40 has low flexibility. This expands the possibility of the location of the solar cell module 100 to be installed. The number or arrangement of the slits 32 may be determined as appropriate depending on the situations.

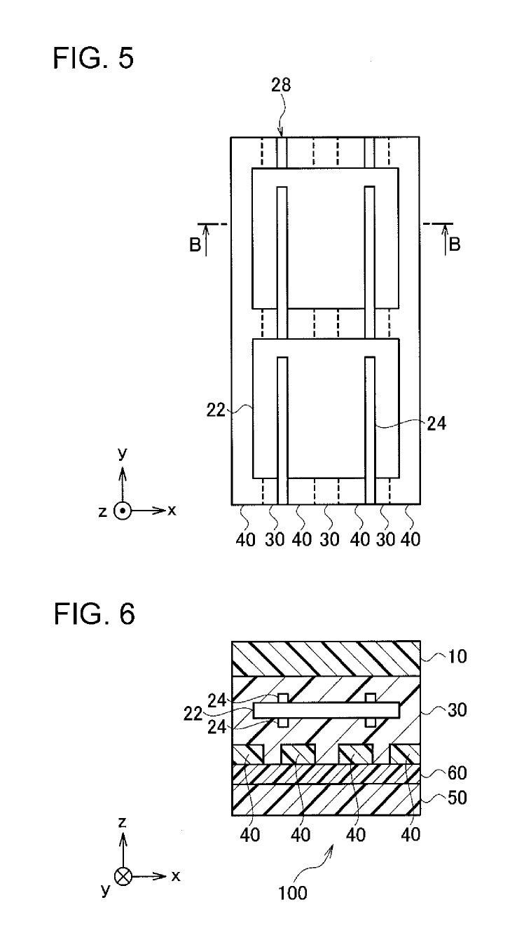

As illustrated with the embodiment shown in FIG. 5 and FIG. 6, at least part of the seal layer 30 may be bonded to the stress-reducing resin layer 60. Since the seal layer 30 typically has higher flexibility than the low thermal expansion-contraction layer 40, the partial bonding of the seal layer 30 with the stress-reducing resin layer 60 can further increase the flexibility of the entire solar cell module 100. This facilitates the bending of the rear surface substrate 50 on the x-y axis plane, not just in a single-axis direction of the x-axis direction or the y-axis direction, for example. The partial bonding of the seal layer 30 with the stress-reducing resin layer 60 may be either in a state in which part of the seal layer 30 is in direct contact with the stress-reducing resin layer 60 or in a state in which part of the seal layer 30 is in indirect contact with the stress-reducing resin layer 60 via another layer such as a bonding layer.

When at least part of the seal layer 30 is bonded to the stress-reducing resin layer 60, a proportion of the area of the low thermal expansion-contraction layer 40 to the total area of the rear surface substrate 50 is preferably set in a range of 40% or greater to 90% or less, as viewed in the stacked direction of the low thermal expansion-contraction layer 40 and the rear surface substrate 50. Setting the proportion of the area of the low thermal expansion-contraction layer 40 to the total area of the rear surface substrate 50 (the area proportion of the low thermal expansion-contraction layer 40) to 40% or greater can prevent damage to the photoelectric converter 20 caused by thermal stress. Setting the area proportion of the low thermal expansion-contraction layer 40 to 90% or less can further enhance the flexibility of the rear surface substrate 50 bent on the x-y axis plane. The area proportion of the low thermal expansion-contraction layer 40 set to 90% or less also leads to a decrease in the used amount of the low thermal expansion-contraction layer 40, which is relatively high-priced, reducing the production costs of the solar cell module 100 accordingly. The area proportion of the low thermal expansion-contraction layer 40 is more preferably set in a range of 50% or greater to 80% or less, and still more preferably in a range of 65% or greater to 75% or less.

As illustrated with the embodiment shown in FIG. 5 and FIG. 6, the photoelectric converter 20 can be the solar cell string 28 in which adjacent solar cells 22 are electrically connected to each other via the connecting members 24. When at least part of the seal layer 30 is bonded to the stress-reducing resin layer 60, the low thermal expansion-contraction layer 40 preferably spans and covers the adjacent solar cells 22 as viewed in the stacked direction of the low thermal expansion-contraction layer 40 and the rear surface substrate 50. The arrangement of the low thermal expansion-contraction layer 40 spanning the respective solar cells 22 can prevent the solar cells 22 from shifting due to thermal expansion or contraction. The prevention of shifting of the solar cells 22 can avoid a cutoff of the connecting members 24 caused by the thermal expansion or contraction.

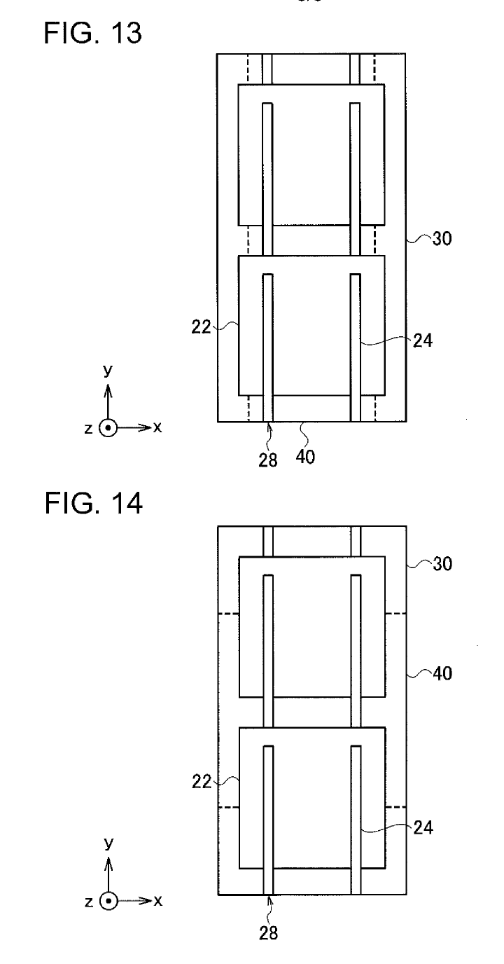

The photoelectric converter 20 is preferably the solar cell string 28 in which adjacent solar cells 22 electrically connected to each other via the connecting members 24. The low thermal expansion-contraction layer 40 preferably covers the entire connecting members 24 as viewed in the stacked direction of the low thermal expansion-contraction layer 40 and the rear surface substrate 50. The length of the low thermal expansion-contraction layer 40 in the direction perpendicular to the connected direction of the solar cells 22 (in the x-axis direction) is preferably smaller than the length of the rear surface substrate 50, as viewed in the stacked direction of the low thermal expansion-contraction layer 40 and the rear surface substrate 50 (refer to FIG. 13). The low thermal expansion-contraction layer 40 with this arrangement can prevent the shift of the solar cells 22 due to thermal expansion or contraction more reliably if the area proportion of the low thermal expansion-contraction layer 40 is the same, thus avoiding a cutoff of the connecting members 24 caused by the thermal expansion or contraction.

<Rear Surface Substrate 50>

The rear surface substrate 50 is arranged under the low thermal expansion-contraction layer 40. The rear surface substrate 50 can protect the surface opposite to the light-receiving surface of the solar cell module 100.

The material included in the rear surface substrate 50 is determined as appropriate, and may be at least one material selected from the group consisting of an inorganic material such as glass, metal such as aluminum, plastic such as polyimide (PI), cyclic polyolefin, polycarbonate (PC), polymethyl methacrylate (PMMA), polyether ether ketone (PEEK), polystyrene (PS), polyethylene terephthalate (PET), and polyethylene naphthalate (PEN), and fiber-reinforced plastic (FRP). Examples of fiber-reinforced plastic (FRP) include glass fiber-reinforced plastic (GFRP), carbon fiber-reinforced plastic (CFRP), aramid fiber-reinforced plastic (AFRP), and cellulose fiber-reinforced plastic. An example of glass fiber-reinforced plastic (GFRP) may be glass epoxy. The rear surface substrate 50 preferably includes glass fiber-reinforced plastic (GFRP) which has a higher resistance to warping and has a lighter weight.

The rear surface substrate 50 is preferably at least one selected from the group consisting of a honeycomb structure, a foamed body, or a porous body. This kind of structure contributes to a reduction in weight of the solar cell module 100 while keeping the rigidity. The material used for the honeycomb structure, the foamed body, or the porous body is determined as appropriate, and may be those as described above. The honeycomb structure preferably includes material containing aluminum or cellulose. At least either the foamed body or the porous body preferably includes resin material such as polyurethane, polyolefin, polyester, polyamide, and polyether.

The coefficient of linear expansion of the rear surface substrate 50 is set in any range which is greater than that of the low thermal expansion-contraction layer 40, and is preferably set in a range of greater than 10×10⁻⁶ K⁻¹ to 70×10⁻⁶ K⁻¹ or smaller. Setting the coefficient of linear expansion in the above range can reduce the thermal stress of the rear surface substrate 50 if a temperature variation is caused in the rear surface substrate 50. The coefficient of linear expansion of the rear surface substrate 50 is more preferably set in a range of greater than 10×10⁻⁶ K⁻¹ to 50×10⁻⁶ K⁻¹ or smaller, and still more preferably in a range of greater than 10×10⁻⁶ K⁻¹ to 30×10⁻⁶ K⁻¹ or smaller.

The tensile modulus of elasticity is preferably, but not necessarily, set in a range greater for the rear surface substrate 50 than for each of the seal layer 30 and the stress-reducing resin layer 60 described below. The rear surface substrate 50 with the greater tensile modulus of elasticity can prevent the solar cell module 100 from being warped. In particular, the tensile modulus of elasticity of the rear surface substrate 50 is preferably set in a range of 1.0 GPa or greater to 50.0 GPa or smaller, and more preferably in a range of 20 GPa or greater to 30 GPa or smaller. The tensile modulus of elasticity can be measured in accordance with the prescription described in JIS K7161-1, for example, as in the case of the front surface substrate 10.

The rear surface substrate 50 preferably, but not necessarily, has a thickness set in a range of 0.1 mm or greater to 10 mm or less, and more preferably in a range of 0.2 mm or greater to 5.0 mm or less. Setting the thickness in the above range can prevent the rear surface substrate 50 from being warped and can further reduce the weight of the solar cell module 100.

The rear surface substrate 50 may be bent to have a curved surface. The bendable rear surface substrate 50 can conform to a shape of a position on which the solar cell module 100 is placed, regardless of whether the installed position of the solar cell module 100 is curved or not. As described above, the low thermal expansion-contraction layer 40 may have slits, or at least part of the seal layer 30 may be bonded to the stress-reducing resin layer 60. This facilitates the bending of the rear surface substrate 50 on the x-y axis plane, not just in a single-axis direction of the x-axis direction or the y-axis direction, for example, as described above.

<Stress-Reducing Resin Layer 60>

The stress-reducing resin layer 60 is arranged between the low thermal expansion-contraction layer 40 and the rear surface substrate 50. The stress-reducing resin layer 60 has a smaller tensile modulus of elasticity than the low thermal expansion-contraction layer 40 and the rear surface substrate 50. The stress-reducing resin layer 60 with the smaller tensile modulus of elasticity can further avoid damage to the photoelectric converter 20 caused by thermal stress.

The material included in the stress-reducing resin layer 60 is determined as appropriate, and may be at least one material selected from the group consisting of an ethylene-vinyl acetate copolymer (EVA), polyvinyl butyral (PVB), polyolefin (PO), urethane, and gel such as silicone gel, acrylic gel, and urethane gel. The material included in the stress-reducing resin layer 60 is particularly preferably polyolefin (PO) in view of the adhesiveness to the adjacent layers and the stress reducing performance.

The coefficient of linear expansion of the stress-reducing resin layer 60 is preferably, but not necessarily, set in a range of greater than 50×10⁻⁶ K⁻¹ to 500×10⁻⁶ K⁻¹ or smaller. The coefficient of linear expansion of the low thermal expansion-contraction layer 40 set in the above range can effectively reduce the thermal stress of the rear surface substrate 50. The coefficient of linear expansion of the low thermal expansion-contraction layer 40 is more preferably set in a range of greater than 100×10⁻⁶ K⁻¹ to 300×10⁻⁶ K⁻¹ or smaller.

The tensile modulus of elasticity of the stress-reducing resin layer 60 is set in any range which is smaller than that of each of the low thermal expansion-contraction layer 40 and the rear surface substrate 50, and is preferably set in a range of 0.005 GPa or greater to 0.5 GPa or smaller. The tensile modulus of elasticity of the stress-reducing resin layer 60 set in the above range can effectively reduce the thermal stress of the rear surface substrate 50. The tensile modulus of elasticity of the stress-reducing resin layer 60 is more preferably set in a range of 0.01 GPa or greater to 0.25 GPa or smaller. The tensile modulus of elasticity of the stress-reducing resin layer 60 is preferably smaller than that of the front surface substrate 10. The tensile modulus of elasticity can be measured in accordance with the prescription described in JIS K7161-1, for example, as in the case of the front surface substrate 10.

The stress-reducing resin layer 60 preferably, but not necessarily, has a thickness set in a range of 0.05 mm or greater to 1.0 mm or less, and more preferably in a range of 0.1 mm or greater to 0.3 mm or less. Setting the thickness of the stress-reducing resin layer 60 in the above range can keep the adhesiveness to the other layers and can effectively reduce the thermal stress of the rear surface substrate 50.

The stress-reducing resin layer 60 preferably has gas barrier properties. In particular, at least either an oxygen transmission rate or a water vapor transmission rate is preferably smaller for the stress-reducing resin layer 60 than for the rear surface substrate 50. The stress-reducing resin layer 60 having such properties can prevent the photoelectric converter 20 from undergoing degradation caused by oxygen or water vapor.

The water vapor transmission rate of the stress-reducing resin layer 60 is preferably, but not necessarily, set in a range of greater than 0 g/(m²·day) to 0.1 g/(m²·day) or smaller. The water vapor transmission rate of the stress-reducing resin layer 60 set in the above range can decrease the content of moisture entering the photoelectric converter 20 to prevent and reduce the degradation of the photoelectric converter 20. The water vapor transmission rate can be measured by an infrared sensing method prescribed in Appendix B to JIS K7129:2008 (Plastics—Film and sheeting—Determination of water vapour transmission rate—Instrumental method), for example. The water vapor transmission rate may be measured under the conditions of a measurement temperature of 40° C. and a measurement humidity of 90% RH.

The oxygen transmission rate of the stress-reducing resin layer 60 is preferably, but not necessarily, set in a range smaller than that of the rear surface substrate 50. The oxygen transmission rate of the stress-reducing resin layer 60 is preferably set in a range of greater than 0 g/(m²·day) to 200 cm³/(m²·day) or smaller. The oxygen transmission rate of the stress-reducing resin layer 60 set in the above range can decrease the content of oxygen entering the photoelectric converter 20 to prevent and reduce the degradation of the photoelectric converter 20. The oxygen transmission rate can be measured in accordance with the prescription described in JIS K7126-2 (Plastics—Film and sheeting—Determination of gas-transmission rate—Part 2: Equal-pressure method). The oxygen transmission rate may be measured under the conditions of a measurement temperature of 23° C. and a measurement humidity of 90% RH.

The solar cell module 100 preferably further includes other elements such as a frame, a gas barrier layer 70, and an insulating layer 90, without impairing the effects according to the present embodiment. The frame is used to protect edge portions of the solar cell module 100, and is also used upon the installation of the solar cell module 100 on a roof, for example.

<Gas Barrier Layer 70>

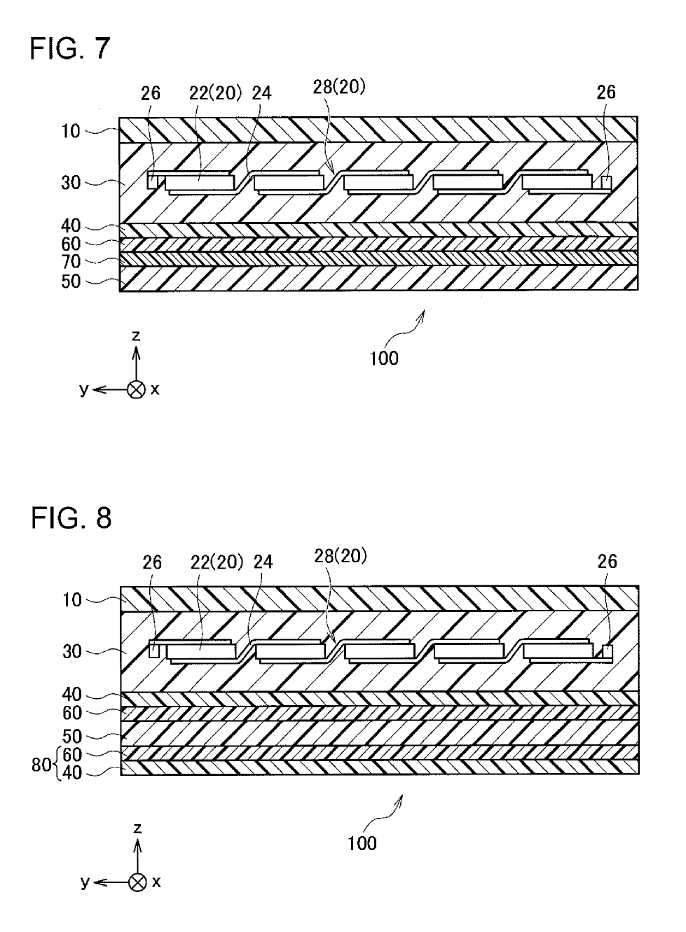

As shown in FIG. 7, the solar cell module 100 according to the present embodiment preferably further includes the gas barrier layer 70 arranged between the stress-reducing resin layer 60 and the rear surface substrate 50 and having at least either an oxygen transmission rate or a water vapor transmission rate smaller than that of the rear surface substrate 50. The inclusion of the gas barrier layer 70 in the solar cell module 100 can prevent the photoelectric converter 20 from undergoing degradation caused by oxygen or water vapor. The solar cell module 100, when including the stress-reducing resin layer 60 having the gas barrier properties as described above, does not necessarily include the gas barrier layer 70. In order to enhance the gas barrier properties and reduce the production costs, the solar cell module 100 preferably includes the gas barrier layer 70, or either the oxygen transmission rate or the water vapor transmission rate is preferably smaller for the stress-reducing resin layer 60 than for the rear surface substrate 50.

The water vapor transmission rate of the gas barrier layer 70 is set in any range which is smaller than that of the rear surface substrate 50, and is preferably set in a range of greater than 0 g/(m²·day) to 0.1 g/(m²·day) or smaller. The water vapor transmission rate of the gas barrier layer 70 set in the above range can decrease the content of moisture entering the photoelectric converter 20 to prevent and reduce the degradation of the photoelectric converter 20. The water vapor transmission rate can be measured by an infrared sensing method prescribed in Appendix B to JIS K7129:2008 (Plastics—Film and sheeting—Determination of water vapour transmission rate—Instrumental method), for example. The water vapor transmission rate may be measured under the conditions of a measurement temperature of 40° C. and a measurement humidity of 90% RH.

The oxygen transmission rate of the gas barrier layer 70 is set in any range which is smaller than that of the rear surface substrate 50, and is preferably set in a range of greater than 0 g/(m²·day) to 200 cm³/(m²·day) or smaller. The oxygen transmission rate of the gas barrier layer 70 set in the above range can decrease the content of oxygen entering the photoelectric converter 20 to prevent and reduce the degradation of the photoelectric converter 20. The oxygen transmission rate can be measured in accordance with the prescription described in JIS K7126-2 (Plastics—Film and sheeting—Determination of gas-transmission rate—Part 2: Equal-pressure method). The oxygen transmission rate may be measured under the conditions of a measurement temperature of 23° C. and a measurement humidity of 90% RH.

The gas barrier layer 70 preferably, but not necessarily, has a thickness set in a range of 0.05 mm or greater to 1.0 mm or less, and more preferably in a range of 0.1 mm or greater to 0.3 mm or less. Setting the thickness in the above range can keep the gas barrier properties sufficiently, while avoiding an increase in cost.

<Warp Prevention Layer 80>

As shown in FIG. 8, the solar cell module 100 according to the present embodiment preferably further includes a warp prevention layer 80. The warp prevention layer 80 may be arranged so as to equalize the thermal expansion or contraction with that of another layer arranged on the other surface of the rear surface substrate 50. In particular, the warp prevention layer 80 may include a set of the low thermal expansion-contraction layer 40 and the stress-reducing resin layer 60 to be arranged on each surface of the rear surface substrate 50. The low thermal expansion-contraction layer 40 and the stress-reducing resin layer 60 are preferably symmetrically arranged about the rear surface substrate 50 in the stacked direction. In particular, the low thermal expansion-contraction layer 40, the stress-reducing resin layer 60, the rear surface substrate 50, the stress-reducing resin layer 60, and the low thermal expansion-contraction layer 40 are sequentially stacked in this order. The use of the warp prevention layer 80 avoids or reduces a warp of a stacked substrate including the low thermal expansion-contraction layer 40, the stress-reducing resin layer 60, and the rear surface substrate 50 caused by thermal expansion or contraction after molding, and is thus particularly preferable when the stacked substrate of the low thermal expansion-contraction layer 40, the stress-reducing resin layer 60, and the rear surface substrate 50 is prepared as a component independent of the front surface substrate 10 and the seal layer 30, facilitating the handling of the solar cell module 100 during manufacture accordingly. As used herein, the term “warp” refers to deformation, which is different from an intentional shape including intentionally-curved shape, since the solar cell module 100 according to the present embodiment can be either a flat plate or a curved plate.

<Insulating Layer 90>

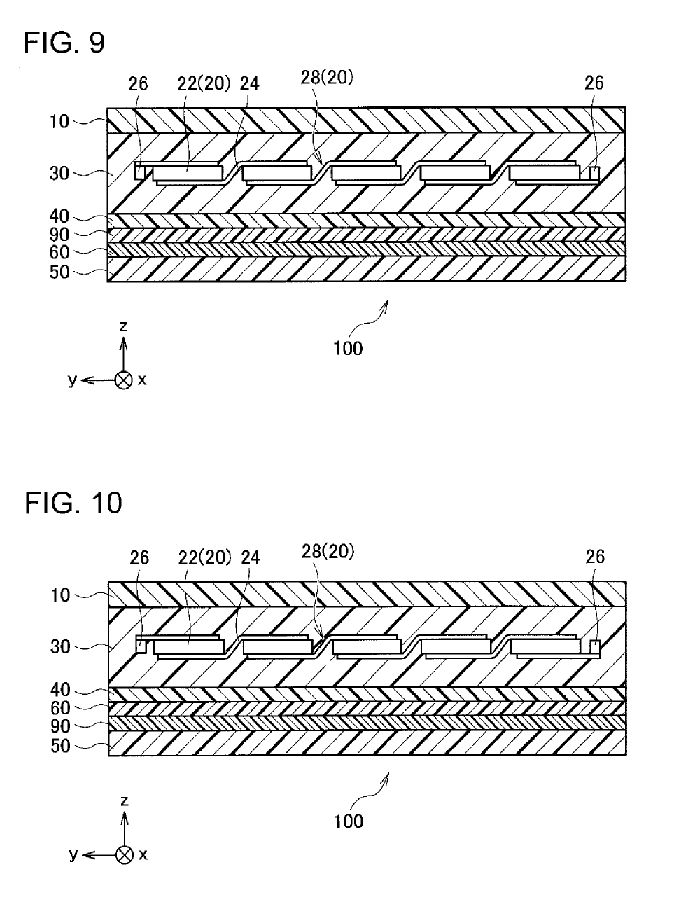

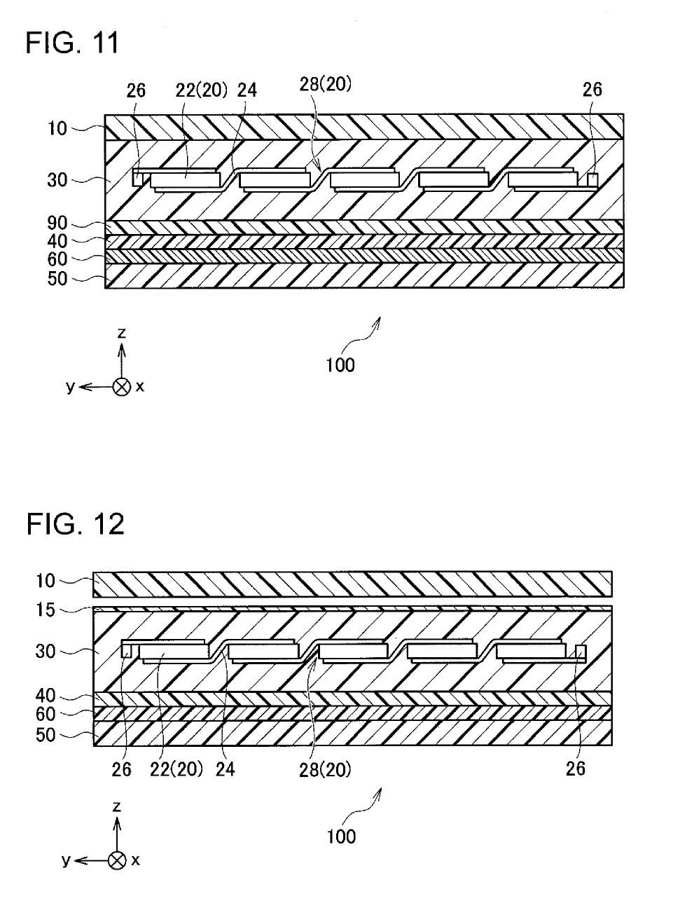

The solar cell module 100 according to the present embodiment may further include the insulating layer 90 arranged under the low thermal expansion-contraction layer 40 and over the rear surface substrate 50. In particular, as shown in FIG. 9, the solar cell module 100 according to the present embodiment may include the insulating layer 90 arranged between the low thermal expansion-contraction layer 40 and the stress-reducing resin layer 60. Alternatively, as shown in FIG. 10, the solar cell module 100 according to the present embodiment may include the insulating layer 90 arranged between the stress-reducing resin layer 60 and the rear surface substrate 50. The arrangement of the insulating layer 90 can keep the electrical insulation of the solar cell module 100 on the side opposite to the light-receiving surface side, namely, on the installation side of the solar cell module 100. The insulating layer 90 leads the solar cell module 100 to be externally insulated on the installation side if the low thermal expansion-contraction layer 40 includes an electrically-conductive carbon material which hinders the electrical insulation. Alternatively, as shown in FIG. 11, the solar cell module 100 according to the present embodiment may include the insulating layer 90 arranged under the seal layer 30 and over the low thermal expansion-contraction layer 40. Such arrangement of the insulating layer 90 can keep the electrical insulation between the photoelectric converter 20 and the low thermal expansion-contraction layer 40 if the low thermal expansion-contraction layer 40 includes an electrically-conductive carbon material.

The insulating layer 90 preferably, but not necessarily, has insulation resistance which fulfills the requirements for an insulation test prescribed in JIS C8990:2009 (Crystalline silicon terrestrial photovoltaic (PV) modules—Design qualification and type approval). In particular, for a module having an area of smaller than 0.1 m², the insulation resistance is preferably 400 MS2 or greater. For a module having an area of 0.1 m² or greater, the product of the measured insulation resistance multiplied by the area of the module preferably results in 40 MΩ·m² or greater.

The insulating layer 90 may include any material that has electrical insulation, such as resin, glass, and cellulose. The insulating layer 90 preferably, but not necessarily, has a thickness set in a range of 0.05 mm or greater to 0.2 mm or less, and more preferably in a range of 0.1 mm or greater to 0.2 mm or less.

<Protective Sheet 15>

The solar cell module 100 according to the present embodiment may further include a protective sheet 15 arranged under the front surface substrate 10 and over the seal layer 30. As shown in FIG. 12, a space is preferably provided between the front surface substrate 10 and the protective sheet 15. In particular, an air layer is preferably provided between the front surface substrate 10 and the protective sheet 15. The front surface substrate 10 can be in no direct contact with the protective sheet 15. The air layer provided in the solar cell module 100 serves as a cushion to absorb external shock, so as to enhance the protective performance toward the photoelectric converter 20.

The protective sheet 15 may include any material, which may be the same as that of the front surface substrate 10. The protective sheet 15 preferably, but not necessarily, has a thickness set in a range of 0.02 mm to 0.3 mm, and more preferably in a range of 0.05 mm to 0.2 mm.

The solar cell module 100 according to the present embodiment described above includes the front surface substrate 10, the seal layer 30 arranged under the front surface substrate 10 to seal the photoelectric converter 20, the low thermal expansion-contraction layer 40 arranged under the seal layer 30, and the rear surface substrate 50 arranged under the low thermal expansion-contraction layer 40. The solar cell module 100 further includes the stress-reducing resin layer 60 arranged between the low thermal expansion-contraction layer 40 and the rear surface substrate 50. The low thermal expansion-contraction layer 40 has a smaller coefficient of linear expansion than the rear surface substrate 50, and the stress-reducing resin layer 60 has a smaller tensile modulus of elasticity than the low thermal expansion-contraction layer 40 and the rear surface substrate 50. This configuration can prevent damage to the photoelectric converter 20 of the solar cell module 100 caused by thermal stress.

<Method of Manufacturing Solar Cell Module 100>

The solar cell module 100 according to the present embodiment can be manufactured by a conventional method. For example, the front surface substrate 10, the seal layer 30, the low thermal expansion-contraction layer 40, the stress-reducing resin layer 60, and the rear surface substrate 50 are sequentially stacked, and then compressed with heating to be molded. The photoelectric converter 20 may be simultaneously placed between the seal layer on the light-receiving surface side and the seal layer on the rear surface substrate 50 side.

The manufacturing method is not limited to specific steps for compressing and molding the respective layers, for example, and may include a molding process which varies depending on the purposes. For example, the low thermal expansion-contraction layer 40, the stress-reducing resin layer 60, and the rear surface substrate 50 may be sequentially stacked, and compressed and molded with heating to prepare a stacked substrate, and the seal layer 30 and the front surface substrate 10 may be further sequentially stacked on the stacked substrate, and then compressed and molded with heating. The solar cell module 100 preferably further includes the warp prevention layer 80 so as to prevent a warp of the stacked substrate caused by thermal contraction of the low thermal expansion-contraction layer 40 and the stress-reducing resin layer 60.

The heating conditions may be determined as appropriate, and the heating process may be undergone at about 150° C. in a vacuum. The heating in a vacuum is preferable so as to enhance the defoaming performance. The respective layers may also be heated with a heater while being pressurized at atmospheric pressure after the vacuum heating, so as to cross-link the resin components together. A frame may be attached to the stacked body obtained by heating.

### EXAMPLES

Hereinafter, the present embodiment is described in more detail with reference to Examples and Comparative Examples, but is not limited to these examples.

### Example 1

A low thermal expansion-contraction layer having a thickness of 0.1 mm, a stress-reducing resin layer having a thickness of 1.0 mm, a rear surface substrate having a thickness of 2 mm, a stress-reducing resin layer having a thickness of 1.0 mm, and a low thermal expansion-contraction layer having a thickness of 0.1 mm were sequentially stacked to prepare a stacked substrate so as to undergo a simulation. The low thermal expansion-contraction layer was carbon fiber-reinforced plastics (CFRP) having a coefficient of linear expansion of 2.5×10⁻⁶ K⁻¹ and a tensile modulus of elasticity of 60 GPa. The stress-reducing resin layer was polyolefin having a tensile modulus of elasticity of 0.02 GPa. The rear surface substrate was glass epoxy having a coefficient of linear expansion of 20×10⁻⁶ K⁻¹ and a tensile modulus of elasticity of 20 GPa.

### Example 2

A stacked substrate of this example was prepared in the same manner as Example 1, except that the thickness of each stress-reducing resin layer was changed to 0.6 mm.

### Example 3

A stacked substrate of this example was prepared in the same manner as Example 1, except that the thickness of each stress-reducing resin layer was changed to 0.3 mm.

### Example 4

A stacked substrate of this example was prepared in the same manner as Example 1, except that the thickness of each stress-reducing resin layer was changed to 0.1 mm.

### Example 5

A stacked substrate of this example was prepared in the same manner as Example 1, except that the thickness of each stress-reducing resin layer was changed to 0.05 mm.

### Comparative Example 1

A stacked substrate of this example was prepared in the same manner as Example 1, except that the thickness of each stress-reducing resin layer was changed to 0 mm.

[Evaluation]

<Actual Coefficient of Linear Expansion>

An actual coefficient of linear expansion on the surface of the low thermal expansion-contraction layer was measured so as to evaluate the influence of the thermal expansion or contraction of the rear surface substrate exerted on the seal layer or the solar cells. The actual coefficient of linear expansion on the uppermost surface of the low thermal expansion-contraction layer was calculated through the simulation. Table 1 lists the measurement results.

TABLE 1

| | Thickness of | |
|---|---|---|
| | Stress-reducing | Actual Coefficient of Linear |
| | Resin Layer (mm) | Expansion (×10⁻⁶K⁻¹) |
| Example 1 | 1.0 | 2.9 |
| Example 2 | 0.6 | 3.3 |
| Example 3 | 0.3 | 4.2 |
| Example 4 | 0.1 | 6.6 |
| Example 5 | 0.05 | 8.6 |
| Comparative | 0 | 14.9 |
| Example 1 | | |

The results shown in Table 1 revealed that Comparative Example 1 with no stress-reducing resin layers has a larger actual coefficient of linear expansion on the surface of the low thermal expansion-contraction layer due to the thermal expansion or contraction of the rear surface substrate having a large coefficient of linear expansion. Examples 1 to 5 each include the stress-reducing resin layers with a greater thickness, resulting in a lower actual coefficient of linear expansion. The greater thickness of the stress-reducing resin layer is presumed to avoid the influence of the thermal expansion or contraction on the seal layer or the photoelectric converter.

Next, the influence of the presence or absence of the stress-reducing resin layers on the damage to the photoelectric converter was determined in the following examples:

### Example 6

A front surface substrate having a thickness of 1 mm, a gel having a thickness of 1 mm, a seal layer on the light-receiving surface side having a thickness of 0.6 mm in which a photoelectric converter was sealed, a seal layer on the rear surface substrate side having a thickness of 0.6 mm, and the stacked substrate prepared in Example 3 were sequentially stacked, and compressed and heated at a temperature of 145° C. so as to fabricate a solar cell module. The front surface substrate was polycarbonate (PC). The photoelectric converter was obtained such that solar cells were connected to each other via connecting tabs (connecting members). The seal layer on the light-receiving surface side was polyolefin (PO), and the seal layer on the rear surface substrate side was an ethylene-vinyl acetate copolymer (EVA).

### Comparative Example 2

A solar cell module of this example was fabricated in the same manner as Example 6, except that the stacked substrate prepared in Example 3 and used in Example 6 was replaced with the stacked substrate prepared in Comparative Example 1.

[Evaluation]

<Resistance to Thermal Shock>

A test for resistance to thermal shock was carried out in accordance with a temperature cycle test prescribed in JIS C8990:2009 (IEC 61215:2005, Crystalline silicon terrestrial photovoltaic (PV) modules—Design qualification and type approval) under the following test conditions: The solar cell module obtained in the respective examples was placed in a test tank to change the temperature of the solar cell module between −40° C.±2° C. and 85° C.±2° C. at periodic intervals. This procedure was regarded as a single cycle, and the cycle was repeated 200 times in the temperature cycle test to visually check the connecting members connecting the solar cells so as to determine whether the connecting members were cut off after 200 cycles. The velocity of change in temperature between the lower limit and the upper limit was set to 1.4° C. per hour, the time of retention of the lower limit temperature was set to 60 minutes, the time of retention of the upper limit temperature was set to 1 hour and 20 minutes, and the time taken in one cycle was set to 5 hours and 20 minutes. The temperature cycle test was repeated at least three times.

TABLE 2

| | Thickness of Stress-reducing | State of connecting tabs |
|---|---|---|
| | Resin Layer (mm) | after 200 cycles |
| Example 6 | 0.3 | No cutoff |
| Comparative | 0 | Cut off |
| Example 2 | | |

The temperature cycle test carried out for Example 6 and Comparative Example 2 to evaluate the resistance to thermal shock, revealed that the connecting members in the solar cell module of Example 6 were not cut off after 200 cycles, while the connecting members in the solar cell module of Comparative Example 2 were cut off after 200 cycles, as shown in Table 2. The damage to the photoelectric converter thus could be determined to be prevented due to the stress-reducing resin layers included in the solar cell module.

Next, how the photoelectric converter was transformed depending on the proportion of the area of the low thermal expansion-contraction layer to the total area of the rear surface substrate as viewed in the stacked direction of the low thermal expansion-contraction layer and the rear surface substrate, was determined in the following examples:

### Example 7

A front surface substrate, a seal layer, a low thermal expansion-contraction layer, a stress-reducing resin layer, and a rear surface substrate were sequentially stacked, and compressed and heated at a temperature of 145° C. so as to fabricate a solar cell module. The front surface substrate was polycarbonate (PC) having a thickness of 2 mm. The seal layer was obtained such that a gel having a thickness of 1 mm, polyethylene terephthalate (PET) having a thickness of 0.02 mm, an ethylene-vinyl acetate copolymer (EVA) having a thickness of 0.6 mm, and an ethylene-vinyl acetate copolymer (EVA) having a thickness of 0.6 mm were sequentially stacked. A solar cell string was used as a photoelectric converter including two solar cells each having a thickness of 0.15 mm and electrically connected to each other via connecting members, and was arranged between the EVA layers each having a thickness of 0.6 mm. The low thermal expansion-contraction layer was unidirectional carbon fiber-reinforced plastics (UD-CFRP) having a thickness of 0.1 mm. The stress-reducing resin layer was an ethylene-vinyl acetate copolymer (EVA) having a thickness of 0.2 mm. The rear surface substrate was glass epoxy having a thickness of 2 mm.

The proportion of the area of the low thermal expansion-contraction layer to the total area of the rear surface substrate (the area proportion of the low thermal expansion-contraction layer) as viewed in the stacked direction of the low thermal expansion-contraction layer and the rear surface substrate, was set to 100%.

### Example 8

A solar cell module of this example was fabricated in the same manner as Example 7, except that the area proportion of the low thermal expansion-contraction layer was changed to 70%. The low thermal expansion-contraction layer was arranged to extend in the connected direction of the solar cells (in the y-axis direction), and had a shorter length than Example 7 in the direction perpendicular to the connected direction of the solar cells (in the x-axis direction), as viewed in the stacked direction of the low thermal expansion-contraction layer and the rear surface substrate (in the z-axis direction), as shown in FIG. 13. In particular, the length of the low thermal expansion-contraction layer was shorter than the length of the rear surface substrate in the direction perpendicular to the connected direction of the solar cells (in the x-axis direction), as viewed in the stacked direction of the low thermal expansion-contraction layer and the rear surface substrate.

### Example 9

A solar cell module of this example was fabricated in the same manner as Example 8, except that the area proportion of the low thermal expansion-contraction layer was changed to 50%.

### Example 10

A solar cell module of this example was fabricated in the same manner as Example 8, except that the area proportion of the low thermal expansion-contraction layer was changed to 20%.

### Example 11

The area proportion of the low thermal expansion-contraction layer was set to 99%. The low thermal expansion-contraction layer was arranged to extend in the direction perpendicular to the connected direction of the solar cells (in the x-axis direction), and had a shorter length than Example 7 in the connected direction of the solar cells (in the y-axis direction), as viewed in the stacked direction of the low thermal expansion-contraction layer and the rear surface substrate (in the z-axis direction), as shown in FIG. 14. In particular, the length of the low thermal expansion-contraction layer was shorter than the length of the rear surface substrate in the connected direction of the solar cells (in the y-axis direction), as viewed in the stacked direction of the low thermal expansion-contraction layer and the rear surface substrate. A solar cell module of this example was fabricated in the same manner as Example 7 except for the changes described above.

### Example 12

A solar cell module of this example was fabricated in the same manner as Example 11, except that the area proportion of the low thermal expansion-contraction layer was changed to 93%.

### Example 13

A solar cell module of this example was fabricated in the same manner as Example 11, except that the area proportion of the low thermal expansion-contraction layer was changed to 70%.

### Example 14

A solar cell module of this example was fabricated in the same manner as Example 11, except that the area proportion of the low thermal expansion-contraction layer was changed to 50%.

### Example 15

A solar cell module of this example was fabricated in the same manner as Example 11, except that the area proportion of the low thermal expansion-contraction layer was changed to 20%.

[Evaluation]

<Variation in Distance Between Solar Cell Modules>

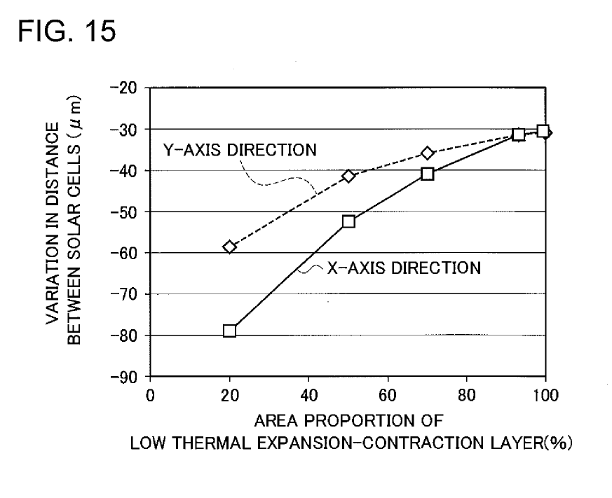

A variation in distance (μm) between the adjacent solar cells in the connected direction in association with the change in thermal load was analyzed with Femtet (registered trademark; available from Murata Software Co., Ltd). The analysis conditions are as follows, and the analysis results are shown in Table 3 and FIG. 15.

<Analysis Conditions>

Model: Plane stress model

Width of solar cells in connected direction (y-axis direction): 140 mm (analysis with ½ symmetry)

Boundary conditions: no fixed parts

Thermal load: Changed from 120° C. to 30° C.

TABLE 3

| | | Area Proportion | Variation |
|---|---|---|---|
| | | of Low Thermal | in Distance |
| | Extending Direction of | Expansion- | between |
| | Low Thermal Expansion- | Contraction | Solar |
| | Contraction Layer | Layer (%) | Cells (μm) |
| Example 7 | y-axis direction (FIG. 13) | 100 | −31 |
| Example 8 | y-axis direction (FIG. 13) | 70 | −36 |
| Example 9 | y-axis direction (FIG. 13) | 50 | −41 |
| Example 10 | y-axis direction (FIG. 13) | 20 | −58 |
| Example 11 | x-axis direction (FIG. 14) | 99 | −30 |
| Example 12 | x-axis direction (FIG. 14) | 93 | −31 |
| Example 13 | x-axis direction (FIG. 14) | 70 | −41 |
| Example 14 | x-axis direction (FIG. 14) | 50 | −52 |
| Example 15 | x-axis direction (FIG. 14) | 20 | −79 |

FIG. 15 is a graph showing the analysis results of the variation in distance between the solar cells when the thermal load was changed from 120° C. to 30° C. The x axis in the graph of FIG. 15 represents the proportion of the area of the low thermal expansion-contraction layer to the total area of the rear surface substrate (the area proportion of the low thermal expansion-contraction layer) (%), as viewed in the stacked direction of the low thermal expansion-contraction layer and the rear surface substrate. The y axis in the graph of FIG. 15 represents the variation in distance (μm) between the solar cells. The distance between the solar cells is a gap between the respective opposed sides of the adjacent solar cells. The variation in distance between the solar cells results in a positive value when the solar cells are shifted to separate from each other, and results in a negative value when the solar cells are shifted closer to each other.

As shown in FIG. 15, the variation in distance between the solar cells increases, as the area proportion of the low thermal expansion-contraction layer decreases. A comparison between the respective solar cell modules having the same area proportion of the low thermal expansion-contraction layer, revealed that the variation in distance between the solar cells is smaller for Examples 7 to 10 (indicated by “y-axis direction” in FIG. 15) than for Examples 11 to 15 (indicated by “x-axis direction” in FIG. 15). The reason for this is presumed to be that the low thermal expansion-contraction layer covers the photoelectric converter along the connected direction of the solar cells, so as to prevent the shift of the solar cells caused by thermal expansion or contraction.

The entire contents of Japanese Patent Application No. P2016-243171 (filed on Dec. 15, 2016) and Japanese Patent Application No. P2017-159400 (filed on Aug. 22, 2017) are herein incorporated by reference.

While the present subject matter has been described above by reference to the embodiment, it should be understood that the subject matter is not intended to be limited to the above description, and various modifications can be made within the scope of the present subject matter.

### INDUSTRIAL APPLICABILITY

The solar cell module according to the present invention has resistance to damage to the photoelectric converter caused by thermal stress.

### REFERENCE SIGNS LIST

10 FRONT SURFACE SUBSTRATE
20 PHOTOELECTRIC CONVERTER
30 SEAL LAYER
32 SLIT
40 LOW THERMAL EXPANSION-CONTRACTION LAYER
50 REAR SURFACE SUBSTRATE
60 STRESS-REDUCING RESIN LAYER
100 SOLAR CELL MODULE

1. A solar cell module comprising:
a front surface substrate;
a seal layer arranged under the front surface substrate to seal a photoelectric converter;
a low thermal expansion-contraction layer arranged under the seal layer;
a rear surface substrate arranged under the low thermal expansion-contraction layer; and
a stress-reducing resin layer arranged between the low thermal expansion-contraction layer and the rear surface substrate,
the low thermal expansion-contraction layer having a smaller coefficient of linear expansion than the rear surface substrate,
the stress-reducing resin layer having a smaller tensile modulus of elasticity than the low thermal expansion-contraction layer and the rear surface substrate.

2. The solar cell module according to claim 1, wherein the coefficient of linear expansion of the low thermal expansion-contraction layer is 20×10⁻⁶ K⁻¹ or smaller.

3. The solar cell module according to claim 1, wherein the rear surface substrate is at least one selected from the group consisting of a honeycomb structure, a foamed body, and a porous body.

4. The solar cell module according to claim 1, wherein the low thermal expansion-contraction layer and the stress-reducing resin layer are symmetrically arranged about the rear surface substrate in a stacked direction.

5. The solar cell module according to claim 1, wherein the low thermal expansion-contraction layer has a slit penetrating from the seal layer to the stress-reducing resin layer.

6. The solar cell module according to claim 1, wherein at least part of the seal layer is bonded to the stress-reducing resin layer.

7. The solar cell module according to claim 6, wherein a proportion of an area of the low thermal expansion-contraction layer to a total area of the rear surface substrate is in a range of 40% or greater to 90% or less, as viewed in a stacked direction of the low thermal expansion-contraction layer and the rear surface substrate.

8. The solar cell module according to claim 6, wherein:
the photoelectric converter is a solar cell string in which adjacent solar cells are electrically connected to each other via a connecting member; and
the low thermal expansion-contraction layer spans and covers the adjacent solar cells as viewed in a stacked direction of the low thermal expansion-contraction layer and the rear surface substrate.

9. The solar cell module according to claim 6, wherein:
the photoelectric converter is a solar cell string in which adjacent solar cells are electrically connected to each other via a connecting member; and
the low thermal expansion-contraction layer covers the entire connecting member as viewed in a stacked direction of the low thermal expansion-contraction layer and the rear surface substrate.

10. The solar cell module according to claim 5, wherein the rear surface substrate is bent to have a curved surface.

11. The solar cell module according to claim 1, wherein the low thermal expansion-contraction layer includes at least one material selected from the group consisting of carbon fiber-reinforced plastic, glass fiber-containing resin, and cellulose nanofiber.

12. The solar cell module according to claim 1, wherein:
the photoelectric converter is a solar cell string in which adjacent solar cells are electrically connected to each other via a connecting member; and
the coefficient of linear expansion of the low thermal expansion-contraction layer is 20×10⁻⁶ K⁻¹ or smaller in the connected direction of the adjacent solar cells as viewed in the stacked direction of the low thermal expansion-contraction layer and the rear surface substrate.
